(19) United States
(12) Patent Application Publication
(10) Pub. No.: US 2019/0379852 A1
(43) Pub. Date: Dec. 12, 2019

(54) IMAGING DEVICE AND CAMERA

(71) Applicant: CANON KABUSHIKI KAISHA, Tokyo (JP)

(72) Inventor: Hiroo Akabori, Fujisawa-shi (JP)

(21) Appl. No.: 16/429,213

(22) Filed: Jun. 3, 2019

(30) Foreign Application Priority Data
Jun. 11, 2018 (JP) 2018-111246

(51) Int. Cl. H04N 5/3745; H04N 5/341; H01L 27/146; H04N 5/355

(52) U.S. Cl. CPC H04N 5/37455; H04N 5/3559; H01L 27/14603; H04N 5/341

(57) ABSTRACT

An imaging device includes a pixel circuit, an amplification circuit, a control circuit, and an A/D conversion circuit. A value of the input capacitance of the amplification circuit is selectable from input capacitance values. A value of the feedback capacitance of the amplification circuit is selectable from feedback capacitance values. The control circuit sets the gain of the amplification circuit to be first through third gains by setting the value of the input capacitance and the value of the feedback capacitance. The A/D conversion circuit is of a voltage slope comparison type using a reference signal. A change rate per unit-time of the reference signal of a case where the amplification circuit has a minimum gain is smaller than a time change rate of the reference signal of a case where the amplification circuit has a maximum gain.

### BACKGROUND OF THE INVENTION

### Field of the Invention

The present invention relates to an imaging device and a camera.

### Description of the Related Art

An imaging device in which an amplification circuit is provided for each column of pixels is known. Japanese Patent Laid-Open No. 2002-198754 proposes the change of gain by switching the value of the input capacitance of the amplification circuit.

### SUMMARY OF THE INVENTION

In the amplification circuit disclosed in Japanese Patent Laid-Open No. 2002-198754, a plurality of input capacitances are provided, while only a single feedback capacitance is provided. To increase the ratio (gain ratio) of the minimum gain to the maximum gain in the amplification circuit, the physical size of the feedback capacitance is required to be increased or the physical size of the input capacitance is required to be reduced. However, increasing the physical size of the feedback capacitance leads to an increase in chip size. Also, reducing the physical size of the input capacitance faces limitations on miniaturization, and also leads to an increase in the effect of parasitic capacitance. An aspect of the present invention provides a technique for increasing the gain ratio of the amplification circuit.

According to an embodiment, an imaging device comprising: a pixel circuit configured to generate a pixel signal in accordance with a quantity of incident light; an amplification circuit configured to amplify the pixel signal at a gain set by selecting one from a plurality of gains which are switchable in accordance with a ratio between a value of an input capacitance and a value of a feedback capacitance; a control circuit configured to set the value of the input capacitance and the value of the feedback capacitance to set the gain of the amplification circuit; and an A/D conversion circuit configured to convert the pixel signal amplified by the amplification circuit into a digital signal, wherein the value of the input capacitance of the amplification circuit is selectable from a plurality of input capacitance values including a first input capacitance value and a second input capacitance value different from the first input capacitance value, the value of the feedback capacitance of the amplification circuit is selectable from a plurality of feedback capacitance values including a first feedback capacitance value and a second feedback capacitance value different from the first feedback capacitance value, the control circuit sets the gain of the amplification circuit to be a first gain by setting the value of the input capacitance to the first input capacitance value, and by setting the value of the feedback capacitance to the first feedback capacitance value, the control circuit sets the gain of the amplification circuit to be a second gain different from the first gain by setting the value of the input capacitance to the first input capacitance value, and by setting the value of the feedback capacitance to the second feedback capacitance value, the control circuit sets the gain of the amplification circuit to be a third gain different from the first gain and the second gain by setting the value of the input capacitance to the second input capacitance value, and by setting the value of the feedback capacitance to one of the plurality of feedback capacitance values, the A/D conversion circuit is of a voltage slope comparison type using a reference signal, and a change rate per unit-time of the reference signal of a case where the amplification circuit has a minimum gain is smaller than a change rate per unit-time of the reference signal of a case where the amplification circuit has a maximum gain, is provided.

Further features of the present invention will become apparent from the following description of exemplary embodiments with reference to the attached drawings.

### BRIEF DESCRIPTION OF THE DRAWINGS

FIG. 1 is a diagram illustrating an exemplary overall configuration of an imaging device of some embodiments.

FIG. 2 is a diagram illustrating an exemplary circuit configuration of the imaging device of some embodiments.

FIG. 3 illustrates a gain setting of an amplification circuit of some embodiments.

FIG. 4 is a diagram illustrating an effect of the imaging device of some embodiments.

### DESCRIPTION OF THE EMBODIMENTS

Embodiments of the invention are described below with reference to the drawings. Like elements are denoted with the same reference numerals throughout the various embodiments, and redundant descriptions thereof are omitted. Further, the embodiments may be modified and combined as appropriate.

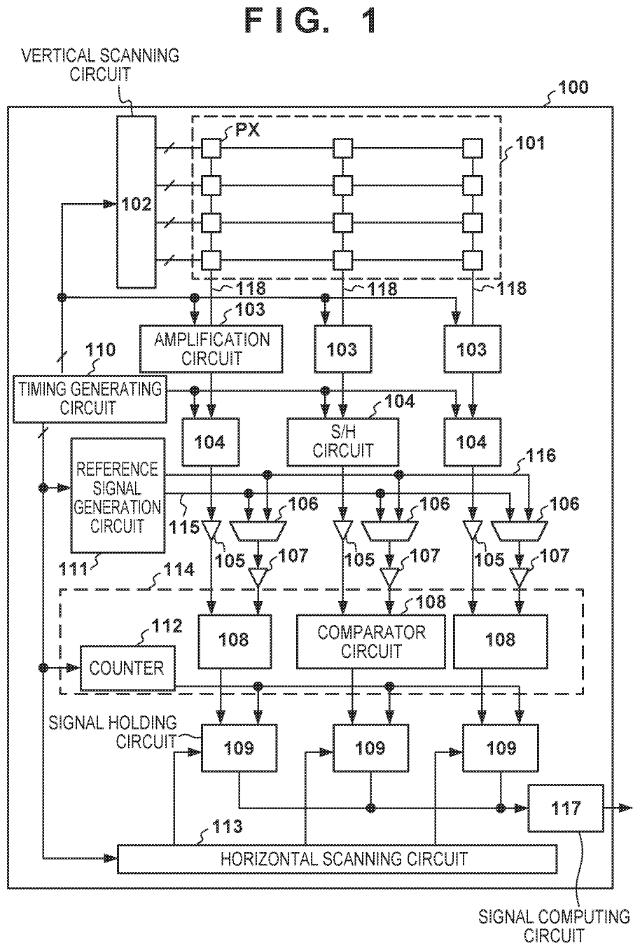

An overall configuration of an imaging device 100 according to some embodiments is described with reference to FIG. 1. The imaging device 100 includes the components illustrated in FIG. 1. The pixel array 101 is composed of a plurality of pixel circuits PX arranged in a matrix. Each pixel circuit PX generates an analog signal in accordance with the quantity of incident light. A vertical scanning circuit 102 sequentially selects each row of the pixel array 101. The analog signals for each pixel circuit PX included in the selected row are read to an amplification circuit 103 corresponding to each column of the pixel array 101. The analog signal generated in the pixel circuit PX includes a noise signal and a pixel signal. The noise signal is a signal that is not dependent on the incident light. The pixel signal is a signal corresponding to the quantity of incident light.

A plurality of signal lines 118 are provided for respective pixel columns of the pixel array 101. A plurality of the amplification circuits 103 are provided for respective signal lines 118. The analog signals are read from the pixels PX to the amplification circuits 103 through the signal lines 118. The amplification circuit 103 amplifies the analog signal read from the pixel circuit PX by a predetermined gain and supplies the amplified signal to a sample and hold circuit 104 (the S/H circuit in the figure). The sample and hold circuit 104 functions as a holding circuit that holds the supplied analog signal. Specifically, the sample and hold circuit 104 performs sampling of the analog signal and holding of the analog signal. The output signal from the sample and hold circuit 104 is supplied to a comparator circuit 108 via a buffer circuit 105. The buffer circuit 105 is composed of a source follower circuit, for example. The buffer circuit 105 performs impedance conversion of the signal input to the buffer circuit 105. As a result, potential fluctuations in the input to the comparator circuit 108 are suppressed. The same applies also to the following buffer circuit 107.

A reference signal generation circuit 111 generates a reference signal that changes with time. As an example of such a reference signal, a ramp signal is described below. The ramp signal is a signal that changes (increases, in this embodiment) at a constant ratio with time. The reference signal generation circuit 111 generates ramp signals of two types, RAMP_H and RAMP_L. The change rate per unit-time of the ramp signal RAMP_H is higher than that of the ramp signal RAMP_L. The reference signal generation circuit 111 supplies the ramp signal RAMP_L through a signal line 115 to a selector 106 and supplies the ramp signal RAMP_H through a signal line 116 to the selector 106.

The selector 106 selects and outputs one of the supplied ramp signals RAMP_H and RAMP_L. The output of the selector 106 is supplied to the comparator circuit 108 via the buffer circuit 107. The comparator circuit 108 compares the value relationship between the input from the buffer circuit 105 and the input from the buffer circuit 107, and outputs a signal of a level corresponding to the comparison result.

A counter 112 provides an increasing count value to a signal holding circuit 109 while a control signal φEN signal is high (i.e., enable period). The signal holding circuit 109 includes a memory circuit, and stores, in the memory circuit, a count value obtained at the time point when the value of the output of the comparator circuit 108 is switched. Thus, an A/D conversion circuit 114 of a voltage slope comparison type using a reference signal, is composed of a combination of the counter 112 and the comparator circuit 108. The A/D conversion circuit converts the analog signal held in the sample and hold circuit 104 into a digital signal. The memory circuit of the signal holding circuit 109 stores the digital signal.

The horizontal scanning circuit 113 sequentially selects a plurality of the signal holding circuits 109. With this selection, the digital signal stored in the memory circuit is read to a signal computing circuit 117. The signal computing circuit 117 performs operations on the digital signal, and thereafter outputs that signal to the outside of the imaging device 100. A timing generating circuit 110 controls operations by generating and supplying control signals to each circuit of the imaging device 100. As such, the timing generating circuit 110 may be referred to as a control circuit.

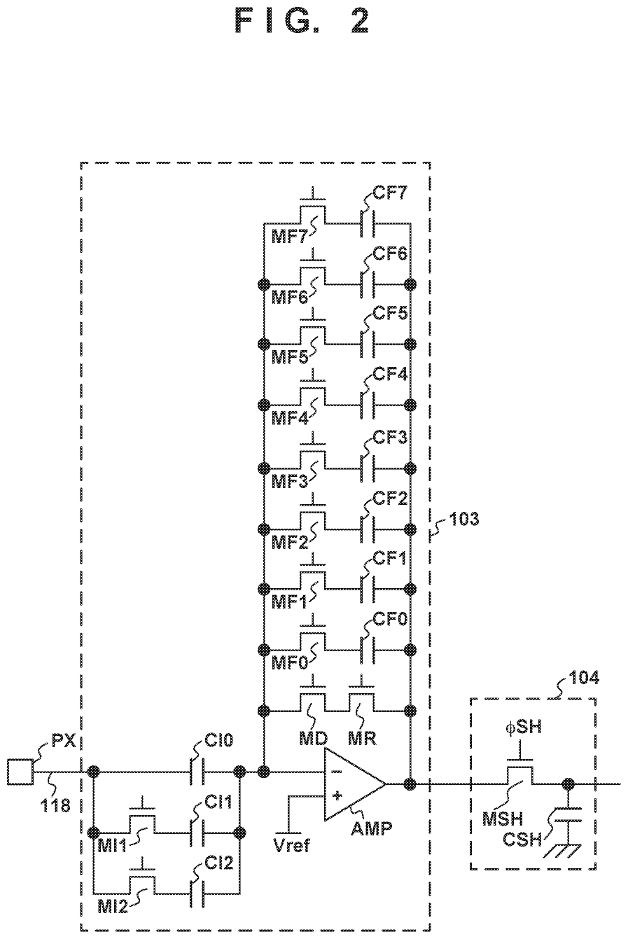

With reference to FIG. 2, an exemplary specific circuit configuration of the amplification circuit 103 and the sample and hold circuit 104 included in the imaging device 100 is described below. The circuit configuration of the pixel circuit PX may be an existing configuration, and therefore detailed descriptions thereof are omitted. The pixel circuit PX includes, for example, a photoelectric conversion element that converts incident light into charge, a floating diffusion (FD) that converts charge to a voltage, and a transfer transistor that transfers charge from the photoelectric conversion element to the FD. The pixel circuit PX further includes an amplification transistor that constitutes a source follower for amplifying and reading a voltage of the FD, a selection transistor for selecting a pixel to read a signal to the signal line, and a reset transistor for resetting the potential of the FD.

The amplification circuit 103 includes an operational amplifier AMP, a plurality of capacitances CI0 to CI2 and CF0 to CF7, and a plurality of transistors MI1 to MI2, MF0 to MF7, MD and MR. Any of these transistors may be MOS transistors. The on/off of each transistor is controlled by the level of the control signal supplied from the timing generating circuit 110 to the control terminal of each transistor. Thus, each transistor functions as a switch element.

The analog signal from the pixel circuit PX is supplied to the inverting input terminal of the operational amplifier AMP via the capacitance CI0. The transistor MI1 and the capacitance CI1 are connected in series between both ends of the capacitance CI0. The transistor MI2 and the capacitance CI2 are connected in series between both ends of the capacitance CI0.

The transistor MR and the transistor MD are connected in series between the inverting input terminal and the output terminal of operational amplifier AMP. The transistor MR is a switch for resetting the amplifier AMP. The transistor MD is a dummy switch for reducing the charge injection of the transistor MR. The transistor MF0 and the capacitance CF0 are connected in series between the inverting input terminal and the output terminal of the operational amplifier AMP. In addition, the transistors MF1 to MF7 and the capacitances CF1 to CF7 are also connected in the same manner as the transistor MF0 and the capacitance CF0. A voltage Vref is supplied to the non-inverting input terminal of the operational amplifier AMP.

The sample and hold circuit 104 includes a transistor MSH and a capacitance CSH. The transistor MSH is connected between the amplification circuit 103 and the buffer circuit 105. One terminal of the capacitance CSH is connected to a node between the transistor MSH and the buffer circuit 105. The on/off of the transistor MSH is controlled by the level of the control signal supplied from the timing generating circuit 110 to the control terminal of the transistor MSH. Thus, the transistor MSH functions as a switch element. While the transistor MSH is on, the sample and hold circuit 104 is in a sampling state in which the output signal from the amplification circuit 103 is written to the capacitance CSH. While the transistor MSH is off, the sample and hold circuit 104 is in a hold state in which the signal of the capacitance CSH is held.

The timing generating circuit 110 sets the gain of the amplification circuit 103 by switching between on and off of each of the transistors MI1 to MI2 and MF0 to MF7. For example, when the transistor MI1 is on, the capacitance CI1 is connected in parallel to the capacitance CI0, and the capacitance CI1 functions as the input capacitance of the amplification circuit 103. As a result, the input capacitance value of the amplification circuit 103 is increased. On the other hand, when the transistor MI1 is off, the capacitance CI1 does not function as the input capacitance of the amplification circuit 103. The same applies to the capacitance CI2. In addition, when the transistor MF0 is on, the capacitance CF0 is connected in parallel to the amplifier AMP, and the capacitance CF0 functions as the feedback capacitance of the amplification circuit 103. As a result, the feedback capacitance value of the amplification circuit 103 is increased. On the other hand, when the transistor MF0 is off, the capacitance CF0 does not function as the feedback capacitance of the amplification circuit 103. In the following example, the capacitance CI0 has a capacitance value of 200 femtofarad (fF), the CI1 capacity has a capacitance value of 140 fF, and the CI2 capacity has a capacitance value of 60 fF. In addition, each of the capacitances CF0 to CF7 has a capacitance value of 50 fF.

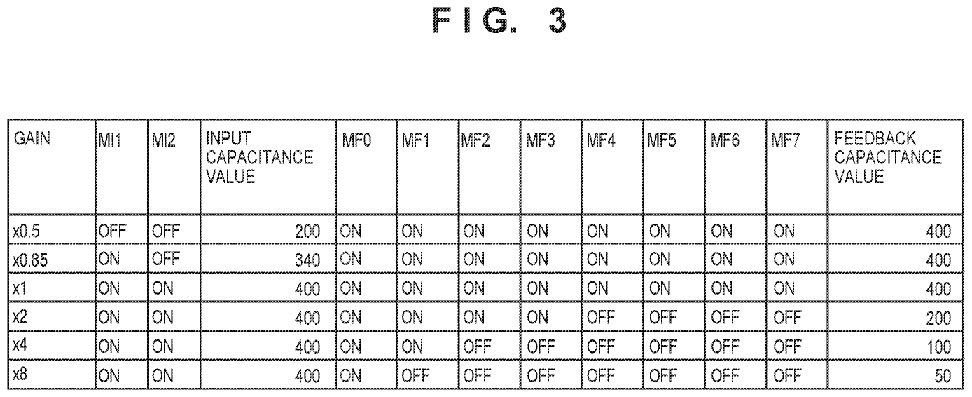

As illustrated in FIG. 3, the timing generating circuit 110 can set the gain of the amplification circuit 103 to be a gain selected from among six levels by switching the value of the feedback capacitance and/or the value of the input capacitance. The minimum gain is 0.5 times and the maximum gain is 8 times. The value of the input capacitance of the amplification circuit 103 can be selected from among a plurality of input capacitance values (200 fF, 340 fF, and 400 fF in this example). Also, the value of the feedback capacitance of the amplification circuit 103 can be selected from among a plurality feedback capacitance values (50 fF, 100 fF, 200 fF, and 400 fF in this example). The gain of the amplification circuit 103 is determined by the ratio between the input capacitance value and the feedback capacitance value.

For example, when setting the gain of the amplification circuit 103 to 0.5 times, the timing generating circuit 110 turns off the transistors MI1 to MI2 and turns on the transistors MF0 to MF7. In other words, the timing generating circuit 110 selects 200 fF as the input capacitance value, and selects 400 fF as the feedback capacitance value. When setting the gain of the amplification circuit 103 to 1 time, the timing generating circuit 110 turns on the transistors MI1 to MI2 and MF0 to MF7. In other words, the timing generating circuit 110 selects 400 fF as the input capacitance value, and selects 400 fF as the feedback capacitance value. When setting the gain of the amplification circuit 103 to 8 times, the timing generating circuit 110 turns on the transistors MI1 to MI2 and MF0 and turns off the transistors MF1 to MF7. In other words, the timing generating circuit 110 selects 400 fF as the input capacitance value and selects 50 fF as the feedback capacitance value. The on/off of the transistors is set also for other gains as illustrated in FIG. 3. A gain (e.g., 1 time) that is greater than the minimum gain and smaller than the maximum gain is referred to as an intermediate gain. The timing generating circuit 110 selects the same feedback capacitance value (400 fF) for each gain (0.5 times, 0.85 times and 1 time) that is equal to or greater than the minimum gain and is equal to or smaller than the intermediate gain. The timing generating circuit 110 selects the same input capacitance value (400 fF) for each gain (1 time, 2 times, 4 times and 8 times) that is equal to or greater than the intermediate gain and is equal to or smaller than the maximum gain.

In the present embodiment, the maximum gain is 8 times and the minimum gain is 0.5 times, and accordingly, the gain ratio is 16. On the other hand, the maximum capacity of the capacitances CI0 to CI2 that can function as the input capacitance is 200 fF, and the maximum capacity of the capacitances CF0 to CF7 that can function as the feedback capacitance is 50 fF, and accordingly, the ratio is 4. Thus, according to the present embodiment, the gain ratio can be greater than the ratio of the capacitance.

Also, the capacitances CF0 to CF7 that can be used as the feedback capacitance have equal capacitance values (50 fF). The timing generating circuit 110 selects the capacitance value of the feedback capacitance by switching the number of capacitances used as the feedback capacitance among the eight capacitances. When switching the gain, the timing generating circuit 110 switches the capacitances in synchronization with each other. Thus, by selecting the capacitance value by use of the capacitances having capacitance values equal to each other, variations of the capacitances in the manufacture can be equalized.

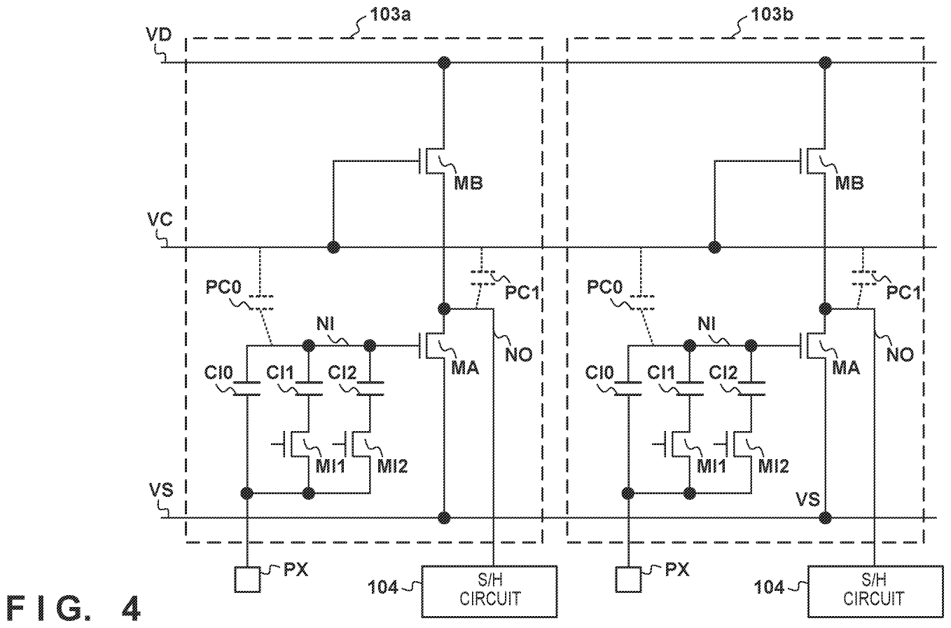

With reference to FIG. 4, an effect of the setting of the gain of the amplification circuit 103 in the above-mentioned manner is described below. FIG. 4 illustrates amplification circuits 103a and 103b corresponding to different columns. Each of the amplification circuits 103a and 103b corresponds to the amplification circuit 103 in FIG. 2. For ease of illustration, the capacitances CF0 to CF7 and the transistors MR, MD and MF0 to MF7 are omitted in the amplification circuits 103a and 103b. While the amplification circuits 103a and 103b are adjacent to each other in the illustration, they may correspond to respective columns that are not adjacent to each other.

A transistor MA is a common source transistor that constitutes the amplifier AMP. The gate of the transistor MA functions as an input terminal. The node to which the input terminal is connected is referred to as a node NI. The drain of the transistor MA functions as an output terminal. The node to which the output terminal is connected is referred to as a node NO. The source of the transistor MA is connected to a power source line VS to which the supply voltage is supplied.

A transistor MB is a current source transistor that controls the gate by a bias voltage in accordance with the drive current setting. The gate of the transistor MB is connected to a control line VC. The source of the transistor MB is connected to a power source line VD. The drain of the transistor MB is connected to the node NO. A bias voltage is supplied to the gate of the transistor MB through the control line VC.

The power source line VS, the control line VC, and the power source line VD are commonly used for the amplification circuits 103 of all columns. A parasitic capacitance PC0 is present between the control line VC and the node NI. A parasitic capacitance PC1 is present between the control line VC and the node NO.

It is assumed that, in the circuit configuration illustrated in FIG. 4, the value of the pixel signal read to the amplification circuit 103a is zero and the value of the pixel signal read to the amplification circuit 103b is significant in reading of a certain pixel row. Such a situation occurs when, for example, the pixel circuit PX where the pixel signal is read to the amplification circuit 103a is in a dark state, and the pixel circuit PX where the pixel signal is read to the amplification circuit 103b is in a light irradiation state.

When the pixel signal is supplied to the amplification circuit 103b, the voltage at the node NI changes via the input capacitance of the amplification circuit 103b. In response to the change in the voltage at the node NI, the voltage of the control line VC changes via the parasitic capacitance PC0 of the amplification circuit 103b. This is because the impedance of the control line VC increases when a plurality of the amplification circuits 103 are arranged in one dimension. Further, in response to the change in the voltage of the control line VC, the voltage at the node NI of the amplification circuit 103a changes via the parasitic capacitance PC0 of the amplification circuit 103a. Likewise, in response to the change in the voltage at the node NO of the amplification circuit 103b, the voltage at the node NO of the amplification circuit 103a changes via the parasitic capacitance PC1. As a result of such crosstalk in the amplification circuits 103a and 103b, the value of the pixel signal of the pixel circuit PX where no light has been input increases, thus generating a smear. A smear is a phenomenon in which, in a photographing condition where the imaging region partially includes a spot brighter than other regions, a streak of the luminance difference that does not originally exist is formed at the boundary of the bright spot in almost the entire imaging region in the horizontal direction, for example.

The amplitude of the pixel signal supplied to the amplification circuit 103 is greater when the gain of the amplification circuit 103 is the minimum than when the gain of the amplification circuit 103 is the maximum. Accordingly, the smaller the gain of the amplification circuit 103, the greater the voltage variation of the control line VC under the influence of the parasitic capacitances PC0 and PC1. In the present embodiment, the input capacitance value (200 fF) obtained with the minimum gain (0.5 times) is smaller than the input capacitance value (400 fF) obtained with the maximum gain (8 times). Thus, the voltage variation of the control line VC under the influence of the coupling in the case where the amplification circuit 103 has the minimum gain can be set to a small value. As a result, the amount of smear in the image obtained with the imaging device 100 is reduced.

In the other hand, when the input capacitance value is small in the case where the amplification circuit 103 has the maximum gain, the reduction amount of the voltage at the node NI increases under the influence of the charge injection at the time when the transistor MR is turned off. Variations in reduction amount among the amplification circuits 103 generate shading in the image. Shading is a phenomenon in which an image signal is not uniformly output even when a uniform luminance surface is imaged. The reduction amount of the voltage due to charge injection is inversely proportional to the input capacitance value of the amplification circuit 103. In the present embodiment, the input capacitance value (400 fF) obtained with the maximum gain (8 times) is greater than the input capacitance value (200 fF) obtained with the minimum gain (0.5 times), and thus the voltage reduction amount due to charge injection can be reduced. As a result, shading in the image obtained with the imaging device 100 is reduced.

As illustrated in FIG. 3, in the example described above, the input capacitance value obtained with the maximum gain (8 times) is 400 fF, and the input capacitance value obtained with the minimum gain (0.5 times) is 200 fF, which is half of 400 fF. For example, the input capacitance value obtained with the minimum gain (0.5 times) is equal to or smaller than half of the input capacitance value obtained with the maximum gain (8 times). The input capacitance value obtained with the maximum gain (8 times) may be other values equal to or smaller than 500 fF. In the example described above, the pixels PX are arranged in an array. Even with other arrangements, the above-mentioned configuration of the amplification circuit 103 provides the same effects in the case where the voltage of the common control line changes due to the coupling by the input of the pixel signal and other pixel signals are affected.

Further, the combination of the input capacitance value, the feedback capacitance value, and the gain is not limited to the above-mentioned examples. In one example, the input capacitance value may be selected from 400 fF and 200 fF and the feedback capacitance value may be selected from 200 fF, 100 fF, and 50 fF. In such a configuration, the timing generating circuit 110 sets the gain of 1 time by setting the input capacitance value to 200 fF and the feedback capacitance value to 200 fF. Also, the timing generating circuit 110 sets the gain of two times by setting the input capacitance value to 200 fF and the feedback capacitance value to 100 fF. Also, the timing generating circuit 110 sets the gain of 4 times by setting the input capacitance value to 400 fF and the feedback capacitance value to 100 fF. Further, the timing generating circuit 110 sets the gain of 8 times by setting the input capacitance value to 400 fF and the feedback capacitance value to 50 fF.

A modification example of the above-described embodiment is described below. In the modification example, in addition to the gain of the amplification circuit 103, the gain of the pixel signal is further switched by switching the change rate per unit-time of the ramp signal (reference signal) used in the A/D converter 114. For example, the change rate of the ramp signal when the amplification circuit 103 has the minimum gain (0.5 times) is smaller than the change rate of the ramp signal when the amplification circuit 103 has the maximum gain (8 times).

Specifically, when the amplification circuit 103 has the minimum gain (0.5 times), the ramp signal RAMP_L is used, and when the amplification circuit 103 has the maximum gain (8 times), the ramp signal RAMP_H is used. For example, the gain is set to 1 time when the ramp signal RAMP_L is used, and the gain is set to 2 times when the ramp signal RAMP_H is used. The timing generating circuit 110 uses the ramp signal RAMP_L when the gain of the amplification circuit 103 is 0.5 times to 4 times. The timing generating circuit 110 selects and uses the ramp signal RAMP_H and the ramp signal RAMP_L when the gain of the amplification circuit 103 is 8 times. In this manner, the pixel signal can be amplified to a gain of 16 times.

Since the ramp signal is supplied in common to each of the comparator circuits 108, output variations of each column circuit are reduced.

Further, by changing the digital gain of the signal computing circuit 117, the gain of the pixel signal output from the imaging device 100 may be changed. The digital gain may be realized by bit shift, for example. The timing generating circuit 110 amplifies the digital signal by a higher gain when the amplification circuit 103 has the maximum gain (8 times) than when the amplification circuit 103 has the minimum gain (0.5 times). For example, the signal computing circuit 117 uses a digital gain of 1 time when the gain of the amplification circuit 103 is 0.5 times to 4 times. When the gain of the amplification circuit 103 is 8 times, the signal computing circuit 117 selects and uses digital gains of 1 time and 2 times. In this manner, the pixel signal can be amplified to a gain of 16 times.

In the above-described embodiment, the timing generating circuit 110 sets the gain of the amplification circuit 103 by switching the value of the feedback capacitance and/or the value of the input capacitance. The imaging device 100 may have other operation modes. For example, with the operation mode of the embodiment as a first mode, the imaging device 100 may have a second operating mode in which the gain of the amplification circuit 103 is set by switching the value of the feedback capacitance while maintaining the value of the input capacitance at a constant value (e.g., 200 fF or 400 fF).

Below, as an exemplary application of the imaging device according to the embodiments, a camera in which the imaging device is incorporated is described. The concept of the camera includes not only devices that are primarily intended for image capturing, but also devices that supplementally include an image capturing function (such as personal computers and mobile terminals). The camera includes the imaging device according to the present invention, which is illustrated as the embodiment described above, and a signal processing unit that processes information based on a signal output from the imaging device. The processing unit may include a processor that processes digital signals, which are image data. The processor may calculate a defocus amount on the basis of a signal from a pixel having a focus detection function of the imaging device to perform processing of controlling a focus adjustment of an imaging lens on the basis of the calculation. An A/D converter for generating the above-mentioned image data may be provided in the imaging device, or may be provided separately from the imaging device. For example, a so-called stacked sensor may also be employed in which a first substrate including the pixel array 101 and a second substrate including a circuit other than the pixel array 101, such as the amplification circuit 103, the sample and hold circuit 104 and the A/D conversion circuit 114, are stacked. In this example, the second substrate is a semiconductor device for lamination, and the effect of improving image quality can be achieved only with the second substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-111246, filed Jun. 11, 2018, which is hereby incorporated by reference herein in its entirety.

What is claimed is:

1. An imaging device comprising:
a pixel circuit configured to generate a pixel signal in accordance with a quantity of incident light;
an amplification circuit configured to amplify the pixel signal at a gain set by selecting one from a plurality of gains which are switchable in accordance with a ratio between a value of an input capacitance and a value of a feedback capacitance;
a control circuit configured to set the value of the input capacitance and the value of the feedback capacitance to set the gain of the amplification circuit; and
an A/D conversion circuit configured to convert the pixel signal amplified by the amplification circuit into a digital signal, wherein
the value of the input capacitance of the amplification circuit is selectable from a plurality of input capacitance values including a first input capacitance value and a second input capacitance value different from the first input capacitance value,
the value of the feedback capacitance of the amplification circuit is selectable from a plurality of feedback capacitance values including a first feedback capacitance value and a second feedback capacitance value different from the first feedback capacitance value,
the control circuit sets the gain of the amplification circuit to be a first gain by setting the value of the input capacitance to the first input capacitance value, and by setting the value of the feedback capacitance to the first feedback capacitance value,
the control circuit sets the gain of the amplification circuit to be a second gain different from the first gain by setting the value of the input capacitance to the first input capacitance value, and by setting the value of the feedback capacitance to the second feedback capacitance value,
the control circuit sets the gain of the amplification circuit to be a third gain different from the first gain and the second gain by setting the value of the input capacitance to the second input capacitance value, and by setting the value of the feedback capacitance to one of the plurality of feedback capacitance values,
the A/D conversion circuit is of a voltage slope comparison type using a reference signal, and
a change rate per unit-time of the reference signal of a case where the amplification circuit has a minimum gain is smaller than a change rate per unit-time of the reference signal of a case where the amplification circuit has a maximum gain.

2. The imaging device according to claim 1, wherein
the second input capacitance value is greater than the first input capacitance value; and
the control circuit selects the first input capacitance value when setting the amplification circuit to the minimum gain, and selects the second input capacitance value when setting the amplification circuit to the maximum gain.

3. The imaging device according to claim 2, wherein
the second feedback capacitance value is smaller than the first feedback capacitance value; and
the control circuit selects the first feedback capacitance value when setting the amplification circuit to the minimum gain, and selects the second feedback capacitance value when setting the amplification circuit to the maximum gain.

4. The imaging device according to claim 1, wherein
the control circuit is capable of setting the amplification circuit to the minimum gain, the maximum gain, and an intermediate gain that is greater than the minimum gain and smaller than the maximum gain;
the control circuit selects an identical feedback capacitance value for gains that are equal to or greater than the minimum gain and equal to or smaller than the intermediate gain; and
the control circuit selects an identical input capacitance value for gains that are equal to or greater than the intermediate gain and equal to or smaller than the maximum gain.

5. The imaging device according to claim 1, wherein the first input capacitance value is equal to or smaller than half of the second input capacitance value.

6. The imaging device according to claim 1, wherein
the feedback capacitance includes a plurality of capacitances having equal capacitance values; and
the control circuit selects a capacitance value of the feedback capacitance by switching a number of capacitances used as the feedback capacitance among the plurality of capacitances.

7. The imaging device according to claim 1, wherein
the feedback capacitance includes a plurality of capacitances having equal capacitance values; and
the control circuit synchronously switches at least two of the plurality of capacitances when switching the gain of the amplification circuit.

8. The imaging device according to claim 1, wherein
the imaging device further comprises a computing circuit configured to perform an operation on the digital signal; and
the computing circuit amplifies the digital signal by a higher gain when the amplification circuit has the maximum gain than when the amplification circuit has the minimum gain.

9. The imaging device according to claim 1, wherein
the imaging device comprises a plurality of the pixel circuits and a plurality of the amplification circuits;
the plurality of pixel circuits are arranged to form a plurality of columns; and
the plurality of amplification circuits are provided such that each of the plurality of amplification circuits correspond to each of the plurality of columns.

10. An imaging device comprising:
a pixel circuit configured to generate a pixel signal in accordance with a quantity of incident light;
an amplification circuit configured to amplify the pixel signal;
a control circuit configured to set a gain of the amplification circuit; and
an A/D conversion circuit configured to convert the pixel signal amplified by the amplification circuit into a digital signal, wherein
a value of an input capacitance of the amplification circuit is selectable from a plurality of input capacitance values,
a value of a feedback capacitance of the amplification circuit is selectable from a plurality of feedback capacitance values,
in a first operation mode, the control circuit sets the gain of the amplification circuit by switching the value of the feedback capacitance and/or the value of the input capacitance,
in a second operation mode, the control circuit sets the gain of the amplification circuit by switching the value of the feedback capacitance while maintaining the value of the input capacitance at a constant value,
the A/D conversion circuit is of a voltage slope comparison type using a reference signal, and
a change rate per unit-time of the reference signal of a case where the amplification circuit has a minimum gain is smaller than a change rate per unit-time of the reference signal of a case where the amplification circuit has a maximum gain.

11. A camera comprising:
the imaging device according to claim 1; and
a signal processing unit configured to process a signal obtained with the imaging device.

12. A camera comprising:
the imaging device according to claim 10; and
a signal processing unit configured to process a signal obtained with the imaging device.
